(19) United States
(12) Patent Application Publication
(10) Pub. No.: US 2020/0208710 A1
(43) Pub. Date: Jul. 2, 2020

(54) Plate-like member vibration control device

(71) Applicant: HONDA MOTOR CO., LTD., Tokyo (JP)

(72) Inventors: Shunji Suzuki, Wako-shi (JP); Toshizumi Yamaguchi, Wako-shi (JP)

(73) Assignee: HONDA MOTOR CO., LTD., Tokyo (JP)

(21) Appl. No.: 16/725,363

(22) Filed: Dec. 23, 2019

(30) Foreign Application Priority Data
Dec. 27, 2018 (JP) 2018-244726

(51) Int. Cl. F16F 15/00; H01L 41/04; H01L 41/08; F16F 15/02

(52) U.S. Cl. CPC F16F 15/007; H01L 41/042; H01L 41/0825; F16F 2224/0241; F16F 2230/18; F16F 2224/0208; F16F 15/02

(57) ABSTRACT

A vibration control device of a plate-like member 11 includes: a piezoelectric element actuator 14 and a piezoelectric element sensor 15 fixed to a surface of a plate-like member 11; and a control circuit 17 that performs feedback control of operation of the piezoelectric element actuator 14 based on an output voltage of the piezoelectric element sensor 15 so as to suppress vibration of the plate-like member 11. The control circuit 17 applies any voltage in a range where a vibration frequency of the plate-like member 11 is equal to or less than a predetermined value based on characteristics of an output voltage of the piezoelectric element sensor 15 so as not to generate noise in a range of 100 Hz or less. Therefore, by increasing a feedback gain, vibration can be suppressed, and noise generated by the vibration can be reduced.

### CROSS-REFERENCE OF RELATED APPLICATION

This application claims priority of Japanese Patent Application No. 2018-244726 filed in Japan on Dec. 27, 2018, the entire contents of which are incorporated herein by reference.

### TECHNICAL FIELD

The present invention relates to a plate-like member vibration control device including: a piezoelectric element actuator and a piezoelectric element sensor disposed on a surface of a plate-like member; and a control circuit that performs feedback control of operation of the piezoelectric element actuator based on an output voltage of the piezoelectric element sensor so as to suppress vibration of the plate-like member.

### BACKGROUND OF THE INVENTION

An apparatus in which a piezoelectric element sensor (piezoelectric element for detection) and a piezoelectric element actuator (piezoelectric element for vibration control) are fixed to a peripheral wall surface of a damper of a suspension device of an automobile, the piezoelectric element sensor detects its own deformation caused by vibration of the damper as a voltage signal, the voltage signal is amplified with an amplification circuit, and the piezoelectric element actuator is driven to stretch and compress the damper to suppress the vibration is disclosed in Japanese Patent Application Publication No. 2014-206257.

By the way, a piezoelectric element actuator and a piezoelectric element sensor are fixed to a surface of a plate-like member, feedback of an input to the piezoelectric element actuator is performed from a circuit based on a voltage signal output from the piezoelectric element sensor that detects strain generated on a surface of the plate according to film surface vibration of the plate-like member, the vibration of the plate-like member is suppressed, and noise generated by the vibration can be reduced.

In order for the piezoelectric element actuator to exhibit a vibration control effect, it is necessary to set a feedback gain to a value larger than 0 dB. However, as described in detail in the section of Best Mode for Carrying Out the Invention, when the feedback gain is set to a value larger than the feedback gain of 0 dB, the vibration is amplified in a frequency range of 100 Hz or less to generate noise.

In a piezoelectric element sensor/piezoelectric element actuator (SNS/ACT) transfer function described later, in a case where anti-resonance exists at a frequency different from that of an acceleration signal (for example, on a low frequency side closest to a primary mode), a signal is amplified at an anti-resonance frequency to deteriorate a vibration level.

### SUMMARY OF INVENTION

In one aspect, an object of the present invention is to provide a plate-like member vibration control device including a piezoelectric element actuator, a piezoelectric element sensor, and a control circuit, in which amplification of vibration is prevented in a range where a vibration frequency is equal to or less than a predetermined value, a feedback gain is increased, and suppression of the vibration and reduction in noise generated by the vibration are possible.

Furthermore, an object is to prevent amplification of vibration by moving an anti-resonance frequency to a problem-free frequency range (for example, to a low frequency or high frequency side) for a problem that anti-resonance exists and a vibration level is deteriorated.

### Means for Solving the Problem

In order to achieve the above object, a first embodiment of the invention proposes a plate-like member vibration control device including: a piezoelectric element actuator and a piezoelectric element sensor disposed on a plate-like member; and a control circuit that performs feedback control of operation of the piezoelectric element actuator based on an output voltage of the piezoelectric element sensor so as to suppress vibration of the plate-like member, in which the control circuit includes a transfer characteristic converter that applies a voltage of a constant gain to an input portion of the piezoelectric element sensor according to a voltage output from the piezoelectric actuator in a range where the vibration frequency of the plate-like member is equal to or less than a predetermined value, thereby minimizes the gain of the output voltage to the piezoelectric actuator of 100 Hz or less, and adjusts a phase.

A second embodiment of the invention proposes a plate-like member vibration control device having the configuration of the first embodiment, in which positive or negative charges are applied to the input portion of the piezoelectric element sensor in a state where the SNS/ACT transfer function already has anti-resonance, and the anti-resonance frequency is thereby moved to a high frequency side or a low frequency side.

A third embodiment of the invention proposes a plate-like member vibration control device having the configuration of the second embodiment, in which the transfer characteristic converter is connected in parallel to a connection position with the piezoelectric element actuator and a connection position with the piezoelectric element sensor in the control circuit.

### Effect of the Invention

According to the configuration of the first embodiment of the invention, the plate-like member vibration control device includes: a piezoelectric element actuator and a piezoelectric element sensor disposed on a surface of a plate-like member; and a control circuit that performs feedback control of operation of the piezoelectric element actuator based on an output voltage of the piezoelectric element sensor so as to suppress vibration of the plate-like member. Therefore, the vibration of the plate-like member is suppressed, and noise generated by the vibration can be reduced.

The control circuit includes a transfer characteristic converter that changes frequency characteristics (gain and phase) of the output voltage of the piezoelectric element sensor in a range where the vibration frequency of the plate-like member is equal to or less than a predetermined value. Therefore, anti-resonance can be caused to prevent vibration amplification in a range where the vibration frequency of the plate-like member is equal to or less than a predetermined value, a feedback gain can be increased, the vibration can be reduced, and noise generated by the vibration can be reduced.

According to the configuration of the second embodiment of the invention, positive or negative charges are applied to the input portion of the piezoelectric element sensor in a state where the SNS/ACT transfer function already has anti-resonance. Therefore, without changing the plate-like member, the piezoelectric element actuator, and the piezoelectric element sensor, characteristics of the SNS/ACT transfer function can be changed, and the anti-resonance frequency can be moved to a high frequency side or a low frequency side.

According to the configuration of the third embodiment of the invention, the transfer characteristic converter is connected in parallel to the connection position with the piezoelectric element actuator and the connection position with the piezoelectric element sensor in the control circuit. Therefore, a voltage at the connection position with the piezoelectric element actuator can be applied to the connection position with the piezoelectric element sensor in a different loop from the control circuit, and a function of the transfer characteristic converter can be exhibited without any problem.

### BRIEF DESCRIPTION OF THE DRAWINGS

FIG. 1 is a view illustrating a plate-like member including a sensor and an actuator.

FIG. 2 is a view illustrating an entire configuration of a vibration control device.

FIG. 3 is a control block diagram of the vibration control device.

FIGS. 4(A) and 4(B) are Bode diagrams of a loop transfer function of a control system of the vibration control device.

FIG. 5 is an explanatory diagram of operation of a transfer characteristic converter.

### DETAILED DESCRIPTION OF EMBODIMENTS OF THE INVENTION

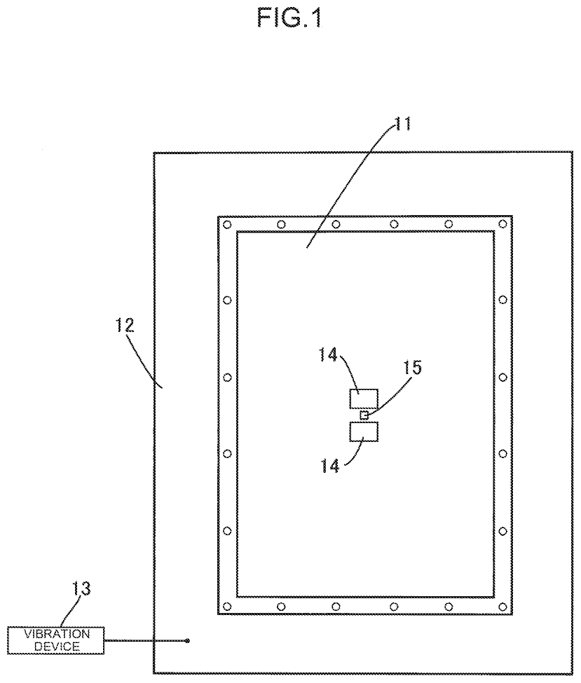

Hereinafter, an embodiment of the present invention will be described based on FIGS. 1 to 5.

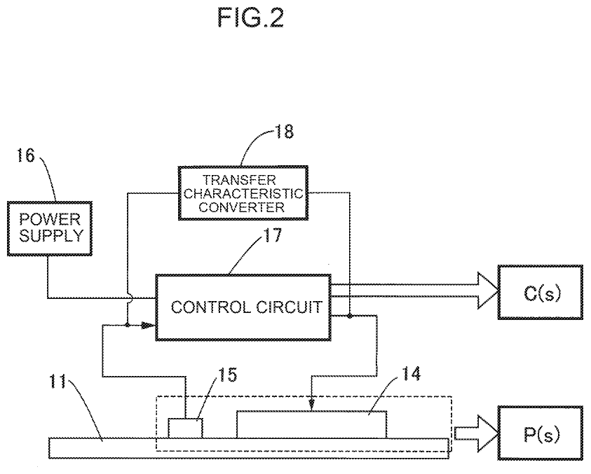

As illustrated in FIGS. 1 and 2, a plate-like member 11 to which a vibration control device of the present invention is applied is formed of a rectangular panel made of a carbon fiber reinforced resin. A metal frame 12 supporting an outer peripheral portion of the plate-like member 11 via an elastic member having sufficiently lower elastic modulus than the metal frame is connected to a vibration device 13 and vibrated at various frequencies. A vibration control device that controls vibration of the plate-like member 11 vibrated by the vibration device 13 includes two rectangular sheet-like piezoelectric element actuators 14, one rectangular sheet-like piezoelectric element sensor 15, a power supply 16, and a control circuit 17 that controls operation of the piezoelectric element actuators 14 based on an output of the piezoelectric element sensor 15. The control circuit 17 includes a transfer characteristic converter 18. The transfer characteristic converter 18 adds a constant gain voltage with any polarity of the circuit depending on the output voltage of the piezoelectric element sensor in all frequency bands.

The one piezoelectric element sensor 15 is fixed to the central portion of one surface (for example, an upper surface) of the plate-like member 11 by adhesion, and the two piezoelectric element actuators 14 are fixed to the upper surface of the plate-like member 11 by adhesion so as to sandwich the one piezoelectric element sensor 15 from both sides.

The piezoelectric element sensor 15 is fixed to the upper surface of the plate-like member 11 that causes film surface vibration in the vertical direction by the vibration device 13. Therefore, when the plate-like member 11 is bent upward convexly, the piezoelectric element sensor 15 is stretched to output a negative voltage. Conversely, when the plate-like member 11 is bent downward convexly, the piezoelectric element sensor 15 is compressed to output a positive voltage.

The piezoelectric element actuators 14 are fixed to the upper surface of the plate-like member 11. Therefore, if a positive voltage is applied to the piezoelectric element actuators 14 and the piezoelectric element actuators 14 are compressed in an in-plane direction when the plate-like member 11 is bent upward convexly, a vibration control force that suppresses the bending of the plate-like member 11 is generated. Conversely, if a negative voltage is applied to the piezoelectric element actuators 14 and the piezoelectric element actuators 14 are stretched in an in-plane direction when the plate-like member 11 is bent downward convexly, a vibration control force that suppresses the bending of the plate-like member 11 is generated.

Therefore, the control circuit 17 performs feedback control of tension and compression of the piezoelectric element actuators 14 such that strain of the plate-like member 11 detected by the piezoelectric element sensor 15 that detects strain of a plate surface due to bending vibration of the plate converges to zero. As a result, the vibration of the plate-like member 11 can be controlled.

In a primary resonance mode or a tertiary resonance mode in which the plate-like member 11 vibrates particularly largely, the central portion of the plate-like member 11 acts as an antinode of vibration and the amplitude is the largest. However, by disposing the piezoelectric element sensor 15 at this position, the strain of the plate-like member 11 can be reliably detected, and the vibration amplified by resonance can be effectively controlled.

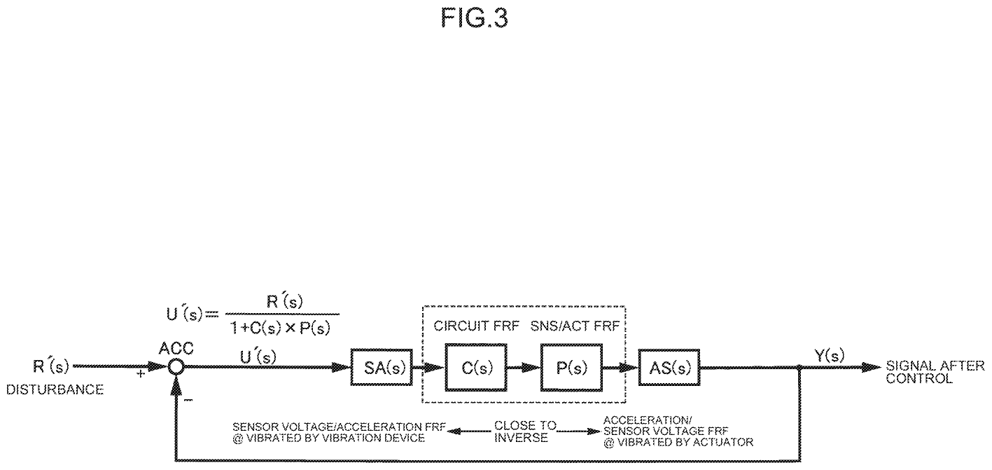

In the block diagram of the control system illustrated in FIG. 3, P(s) [V/V] represents a transfer function of a voltage output from the piezoelectric element sensor 15 with respect to a voltage input to each of the piezoelectric element actuators 14, C(s) [V/V] represents a transfer function of a voltage input to each of the piezoelectric element actuators 14 with respect to a voltage output from the piezoelectric element sensor 15, SA(s) [V/m/s²] represents a sensor voltage/acceleration transfer function when vibration is applied by the vibration device 13, and AS(s) [m/s²/V] represents an acceleration/sensor voltage transfer function when vibration is applied by each of the piezoelectric element actuators 14.

P(s) expressed as an SNS/ACT transfer function is determined by a layout indicating the sizes, the shapes, and the positional relationship of the piezoelectric element actuator 14 and the piezoelectric element sensor 15. C(s) as a transfer function of the control circuit 17 defines the amount of amplification of the control circuit 17. Since SA(s) and AS(s) are approximately in an inverse relationship, the loop transfer function that determines vibration control performance of the control system is represented by [C(s)×P(s)].

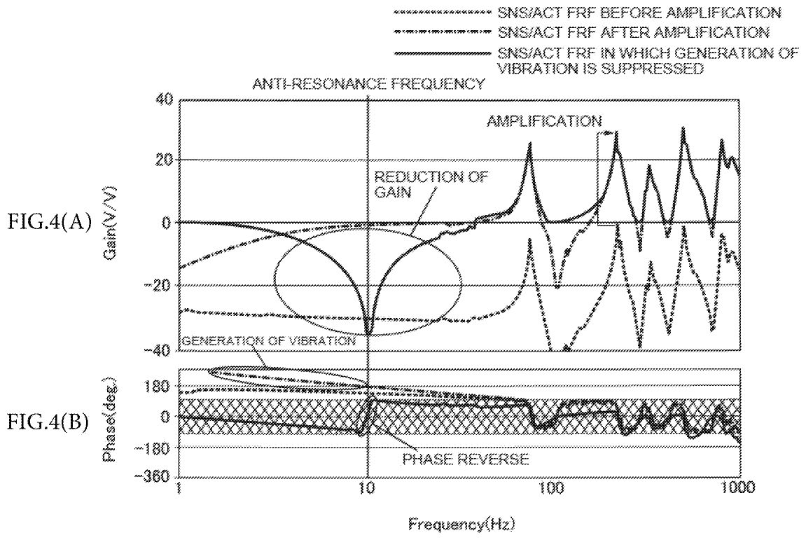

FIGS. 4(A) and 4(B) are Bode diagrams of the loop transfer function [C(s)×P(s)]. FIG. 4(A) is a gain diagram with respect to the vibration frequency of the plate-like member 11. FIG. 4(B) is a phase diagram with respect to the vibration frequency of the plate-like member 11. The broken line indicates the characteristics P(s). The chain line indicates the characteristics in the control circuit 17 after amplification. The solid line indicates the characteristics after suppression of a frequency range of 100 Hz or less is performed and amplification is performed by the control circuit 17. Due to an effect of a high-pass filter described later, in a frequency range of 100 Hz or less, a gain is reduced, and a phase develops as indicated by the one dot chain line.

In order for the piezoelectric element actuator 14 to exhibit an effective vibration control function, the gain needs to be larger than 0 dB, and the phase shift needs to be in a range of −90° to 90°. However, as the characteristics before amplification indicated by the broken line, the gain is less than 0 dB. Therefore, the gain needs to be increased so as to be 0 dB or larger by amplification to be in the state of the chain line. However, in a case where a feedback gain is increased in order to reduce the vibration and the gain becomes larger than 0 dB, the phase shift largely deviates from the range of −90° to 90° to exceed 180° in the vibration frequency range of 100 Hz or less, and the vibration is amplified in this frequency range to generate noise.

A reason why the phase shift exceeds 180° is as follows. Inclusion of a direct current component in an output of the piezoelectric element sensor 15 cannot be avoided due to an influence of temperature change or static deformation. When a vibration component of the output of the piezoelectric element sensor 15 is amplified in a state where the vibration component contains the direct current component, an amplification amount of an amplifier cannot be increased, and vibration control performance cannot be enhanced. Therefore, it is necessary to remove the direct current component using a high-pass filter. However, by using the high-pass filter, not only the gain is reduced but also the phase advances. Therefore, by using two or more high-pass filters, the phase shift may exceed 180°.

The present invention solves the above-described generation of noise of 100 Hz or less by the transfer characteristic converter 18 disposed in the control circuit 17.

That is, the transfer characteristic converter 18 applies a positive or negative voltage between the output voltage of the control circuit 17 and the input voltage thereof with a constant gain for all frequency bands. As a result, a voltage output from a piezoelectric element sensor and a voltage output from the transfer characteristic converter are summed up in a frequency range of 100 Hz or less to cause anti-resonance. As indicated by the solid line in the gain diagram of FIG. 4(A), the gain takes a minimum value, and as indicated by the solid line in the phase diagram of FIG. 4(B), the sign of the phase shift is reversed from positive to negative and falls in a range of −90° to 90°, thereby suppressing generation of noise. Therefore, since the generation of noise can be reliably prevented, the feedback gain can be increased, and the vibration and the noise generated by the vibration can be reduced.

The transfer characteristic converter 18 has a function of changing the characteristics of the SNS/ACT transfer function P(s) without changing the plate-like member 11, the piezoelectric element actuator 14, and the piezoelectric element sensor 15, needs to apply a voltage that has been applied to the piezoelectric element actuator 14 once to a voltage signal input point of the piezoelectric element sensor 15 in a different loop from the control circuit 17, and therefore needs to be connected to the control circuit 17 not in series but in parallel (see FIG. 2).

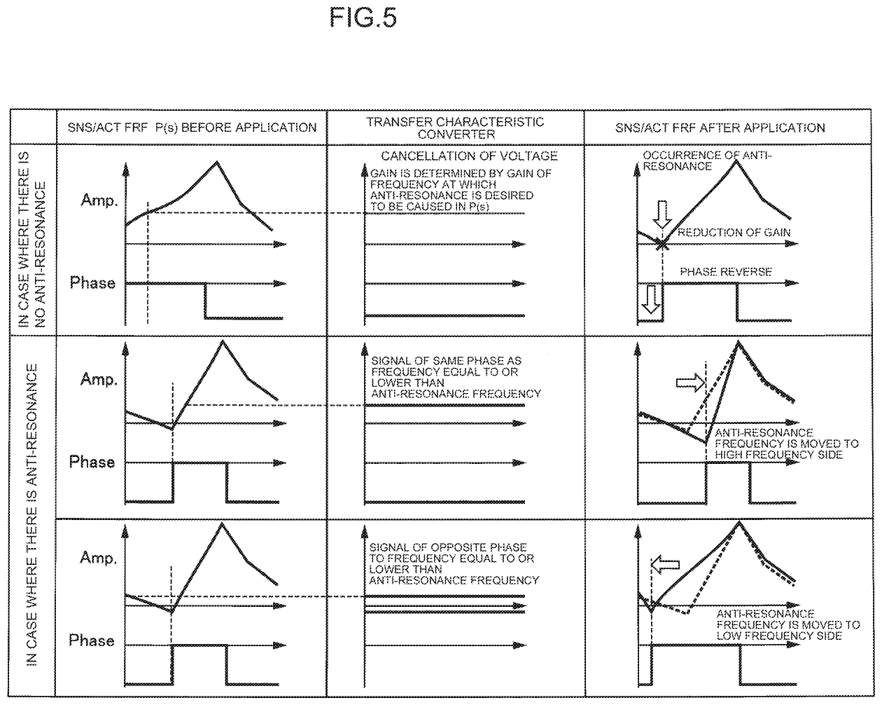

As illustrated in FIG. 5, in a case where the SNS/ACT transfer function P(s) already has anti-resonance, when a voltage of the same phase as a frequency equal to or lower than the frequency at which the anti-resonance occurs is applied, a voltage generated from strain due to bending deformation of the plate-like member 11 is required for cancelling the voltage. Therefore, the frequency can be moved to a high frequency side close to a primary mode. When a voltage of the opposite phase to a frequency equal to or lower than the frequency at which the anti-resonance occurs is applied, the frequency can be moved to a low frequency side for the same reason. In adjusting the gain of the transfer characteristic converter 18, the gain of the transfer characteristic converter 18 needs to be equal to the gain of the SNS/ACT transfer function P(s) at a frequency at which anti-resonance is desired to be caused.

Hitherto, the embodiments of the present invention have been described. However, various design changes of the present invention can be performed in a range not deviating from a gist thereof.

The piezoelectric element actuator 14 and the piezoelectric element sensor 15 are fixed to the same side surface of the plate-like member 11 in the embodiment. However, the piezoelectric element actuator 14 may be fixed to one surface of the plate-like member 11, and the piezoelectric element sensor 15 may be fixed to the other surface of the plate-like member 11. However, the polarity of the output voltage of the piezoelectric element sensor 15 changes depending on a side surface to which the piezoelectric element sensor 15 is fixed. Therefore, the polarity of the output voltage of the piezoelectric element sensor 15 needs to be processed by the control circuit 17 according to a surface to which the piezoelectric element sensor 15 is fixed.

Note that regardless of a surface of the plate-like member 11 to which the piezoelectric element actuator 14 and the piezoelectric element sensor 15 are fixed, the piezoelectric element actuator 14 and the piezoelectric element sensor 15 are desirably disposed at different positions (positions not overlapping with each other, viewed from a direction orthogonal to a surface of the plate-like member 11). This is because when the piezoelectric element actuator 14 and the piezoelectric element sensor 15 are disposed at the same position, the piezoelectric element sensor 15 preferentially detects strain by the piezoelectric element actuator 14, and it is difficult to detect strain due to disturbance to reduce vibration control performance.

The number of the piezoelectric element actuators 14 and the number of piezoelectric element sensors 15 are not limited to those of the embodiment, and the number of the piezoelectric element actuators 14 and the number of the piezoelectric element sensors 15 are arbitrary.

A material of the plate-like member 11 is not limited to the carbon fiber reinforced resin plate of the embodiments, and may be another type of fiber reinforced resin plate or any metal plate such as a steel plate or an aluminum plate.

The piezoelectric element actuator 14 and the piezoelectric element sensor 15 are fixed to the plate-like member 11 by adhesion in the embodiments, but can be fixed by a method other than adhesion, and can be detachably attached.

1. A plate-like member vibration control device comprising:
a plate-like member;
a piezoelectric element actuator and a piezoelectric element sensor which are disposed on the plate-like member; and
a control circuit with an input portion for the piezoelectric element sensor through which an output voltage of the piezoelectric element sensor is inputted to the control circuit, the control circuit being configured to perform feedback control of operation of the piezoelectric element actuator based on the output voltage of the piezoelectric element sensor so as to suppress vibration of the plate-like member, wherein
the control circuit comprises a transfer characteristic converter configured to apply a voltage with a constant gain to the input portion for the piezoelectric element sensor according to the voltage output from the piezoelectric actuator in a range where a vibration frequency of the plate-like member is equal to or less than a predetermined value so as to minimize a gain of the output voltage to the piezoelectric actuator and adjust a phase of the output voltage in which the vibration frequency is 100 Hz or less.

2. The plate-like member vibration control device according to claim 1, wherein the plate-like member vibration control device is configured such that positive or negative charges are applied to the input portion for the piezoelectric element sensor in a state where an SNS/ACT transfer function already has anti-resonance, and an anti-resonance frequency is thereby moved to a higher frequency side or a lower frequency side than when the positive or negative charges are not applied.

3. The plate-like member vibration control device according to claim 2, wherein the transfer characteristic converter is connected in parallel with respect to the control circuit such that the transfer characteristic converter is positioned between a connection position in which the piezoelectric element actuator is connected to the control circuit and a connection position in which the piezoelectric element sensor is connected to the control circuit.
